(19) United States
(12) Patent Application Publication
(10) Pub. No.: US 2025/0054542 A1
(43) Pub. Date: Feb. 13, 2025

(54) Assembly for carrying out a discrete Fourier transform

(71) Applicant: SEMRON GmbH, Dresden (DE)

(72) Inventor: Kai-Uwe DEMASIUS, Dresden (DE)

(73) Assignee: SEMRON GmbH, Dresden (DE)

(21) Appl. No.: 18/687,325

(22) PCT Filed: Sep. 1, 2022
(86) PCT No.: PCT/EP2022/074376

§ 371 Date: Feb. 28, 2024

(30) Foreign Application Priority Data
Sep. 1, 2021 (DE) 10 2021 004 453.3

(51) Int. Cl. G11C 13/00; G06F 17/14

(52) U.S. Cl. CPC G11C 13/004; G06F 17/141; G11C 13/0026; G11C 13/0061

(57) ABSTRACT

A matrix assembly includes: —a matrix of resistive components (5), the resistance values of which represent the coefficients of a discrete Fourier matrix, wherein values representing a first set of input values (1) can be applied to word lines (2) of the matrix, and values representing a second set of output values (3) can be applied to the bit lines (4) of the matrix, the input values (1) being defined by means of phase or amplitude; and —a current amplifier which sums the output values (3) and can be connected to the bit lines (4). The aim of the invention is to allow for an implementation which reduces the number of matrices for a discrete Fourier transform. This aim is achieved in that the matrix assembly also contains capacitive elements, more particularly memcapacitive elements, which can store a capacitive value.

### CROSS-REFERENCE TO RELATED APPLICATION

This application is a national stage application, filed under 35 U.S.C. § 371, of International Patent Application PCT/EP2022/074376, filed on Sep. 1, 2022, which claims the benefit of German Patent Application DE 10 2021 004 453.3, filed on Sep. 1, 2021.

### BACKGROUND

A discrete Fourier transform has a wide variety of applications, for example in audio and image processing or to simplify convolutions in artificial neural networks. One example is determining a spectrogram for voice recognition by means of artificial neural networks. Other applications are solving differential equations.

Computing a discrete Fourier transformer is computationally complex, however, which is why the fast Fourier transform method was developed. The computational complexity continues to be great, however.

In general, a discrete Fourier transform is carried out using a vector matrix multiplication, the discrete Fourier matrix being used:

$$W = \frac{1}{\sqrt{N}} \cdot ( \begin{matrix}1 & 1 & 1 & 1 & … & 1 \\ 1 & ω & {ω}^{2} & {ω}^{3} & … & {ω}^{N - 1} \\ 1 & {ω}^{2} & {ω}^{4} & {ω}^{6} & … & {ω}^{2 ( N - 1 )} \\ 1 & {ω}^{3} & {ω}^{6} & {ω}^{9} & … & {ω}^{3 ( N - 1 )} \\ ⋮ & ⋮ & ⋮ & ⋮ & ⋱ & ⋮ \\ 1 & {ω}^{N - 1} & {ω}^{2 ( N - 1 )} & {ω}^{3 ( N - 1 )} & … & {ω}^{( N - 1 ) ( N - 1 )}\end{matrix} )$$

$$W = {( \frac{{ω}^{jk}}{\sqrt{N}} )}_{j , k = 0 , ... , N - 1}$$

$$with :$$

$$ω = {e}^{\frac{2 π i}{N}}$$

This matrix is multiplied by the discrete time vector (x) in order to obtain the discrete frequency vector (X):

X=Wx

The discrete Fourier matrix thus has complex entries. In order to carry out this vector matrix multiplication efficiently, memresistive matrix assemblies that can perform vector matrix multiplications very efficiently were already proposed (WO2017131711A1). The coefficients of the discrete Fourier matrix are realized by means of adjustable resistance values in the matrix in this instance, for example using memristors in that case. However, carrying out a complex vector matrix multiplication requires a total of 4 vector matrix multiplications, since both the input values and the coefficients of the matrix may be complex:

$$X = ( Re ( W ) + j \cdot Im ( W ) ) \cdot ( Re ( x ) + j \cdot Im ( x ) )$$

This resolves to give:

$$Re ( X ) = Re ( W ) \cdot Re ( x ) - Im ( W ) \cdot Im ( x )$$

$$Im ( X ) = Re ( W ) \cdot Im ( x ) + Im ( W ) \cdot Re ( x )$$

A total of 4 vector matrix multiplications would therefore be necessary, which entails a large area requirement for the 4 matrices. Furthermore, the elements are often split into positive and negative values, meaning that 8 vector matrix multiplications would be required. The use of phase information relating to the input values allows a complex representation of the input value, thereby reducing the number of multiplications (WO2017131711A1).

The application CN113241053 presents a method for actively controlling audio signals. This application belongs to a different technical field, however, and is used primarily for noise rejection in audio signals. Although a discrete Fourier transform is used, it is employed primarily to determine frequency bands and is itself not optimized in the application. Possible delay filters, which may contain capacitive elements, are employed primarily to compensate for delays in the speed of sound or the circuit board. Phase switches are also employed primarily to adapt the filter coefficients and not for the discrete Fourier transform itself.

### SUMMARY

The present disclosure relates to a matrix assembly containing a matrix of resistive devices (5), the resistance values of which represent the coefficients of a discrete Fourier matrix, and values that represent a first set of input values (1) being able to be applied to word lines (2) of the matrix and values that represent a second set of output values (3) being able to be applied to the bit lines (4) of the matrix, and the input values (1) being defined by phase or amplitude, and containing a current amplifier that is able to be connected to the bit lines (4) and sums the output values (3).

An object of this disclosure is to facilitate an implementation that reduces the number of matrices for a discrete Fourier transform.

An assembly of the type cited is configured, by virtue of the matrix assembly also containing capacitive elements, in particular memcapacitive elements, that are designed to be able to store a capacitive value.

The addition of capacitive elements facilitates a complex representation of the matrix, and memcapacitive elements allow the capacitance of the capacitive elements to be altered: A=G+jωC

with admittance A, conductance G and capacitance C.

In a second advantageous embodiment, the input values may additionally be defined by a number of periods.

The output values are therefore integrated with every period and the output value becomes higher the more periods there are in the input value.

In order to split the output values into imaginary and real parts, phase-sensitive amplifiers are required. These are capable of extracting the real and imaginary parts of the output values even if, in contrast to the prior art, the real and imaginary parts are present on the same bit line. The use of a phase-sensitive amplifier is explained in an advantageous embodiment.

In another advantageous embodiment, the phase-sensitive amplifiers contain two input-side switches that switch in opposition, and the switching state is determined by a clock signal and the clock signals for the real part have a 0° phase shift and the clock signals for the imaginary part have a 90° phase shift, with the result that half-cycles of the output signal are always connected to the noninverting and inverting inputs of the phase-sensitive amplifier.

The output signals of the bit line are ultimately switched such that the real component of the output signal in the amplifier provided for the real part, whole positive and negative components are always switched to the noninverting and inverting inputs of the amplifier. All in all, a DC component is therefore obtained in the output of the amplifier, which can be integrated by a capacitor, for example. In the case of the amplifier provided for the imaginary part, partially positive and partially negative components are always switched to the amplifier, with the result that the two parts balance out one another. For the imaginary component of the output signal, the response is the exact opposite, since the clock signal has a 90° phase shift, between the real part amplifier and the imaginary part amplifier. The amplifier may be a transconductance amplifier, for example, the input voltage (output signal from the matrix) being able to be determined by the voltage drop across the parasitic bit line capacitance, and the output current being integrated using an integration capacitor. This integration leads to the number of periods in the input signal likewise being able to determine the level thereof, for example.

In a fifth embodiment, the resistance value of the resistive elements represents the real part of the coefficients of the matrix and the capacitance value of the capacitive elements represents the imaginary part of the coefficients of the matrix.

A disadvantage of this assembly is that resistive components are likewise required, which have a static current consumption.

In another embodiment, the matrix consists exclusively of capacitive elements divided, per matrix coefficient, into positive real and negative real and also positive imaginary and negative imaginary capacitive elements, and a series capacitance is connected in series with the ground connection on the real bit lines and a series resistance is arranged in series with the ground connection on the imaginary bit lines, and the voltage drops across the series capacitance and the series resistance are able to be measured by phase-sensitive amplifiers.

If there is another series capacitance (C_{S}) in series with a capacitance (C_{Re}) and the input signal is in the form of a voltage, the following applies for the flow of current (provided that C_{Re}<<C_{S}):

$$I = j ω {C}_{Re} \cdot {V}_{in}$$

This flow of current leads to the following voltage drop across the series capacitance:

$${V}_{S} = \frac{j ω {C}_{Re}}{j ω {C}_{S}} \cdot {V}_{in} = \frac{{C}_{Re}}{{C}_{S}} \cdot {V}_{in}$$

The capacitance C_{Re} therefore leads to a real shift and is the real part. In the case of a series resistance (R_{S}), the following is obtained:

$${V}_{S} = {R}_{S} \cdot j ω {C}_{Im} \cdot {V}_{in}$$

The capacitance C_{Im} therefore leads to an imaginary shift and is the imaginary part. In this way, the coefficients of the matrix can have a real part and an imaginary part even if the memory cells are only capacitive and do not consist of resistive and capacitive elements.

It is likewise conceivable, in another embodiment, for the matrix to consist exclusively of resistive elements divided, per matrix coefficient, into positive real and negative real and also positive imaginary and negative imaginary resistances, and for a series resistance in relation to the ground connection to be on the real bit lines and for a series capacitance in relation to the ground connection to be arranged on the imaginary bit lines, and for the voltage drops across the series resistances and the series capacitances to be able to be measured by the phase-sensitive amplifiers.

That is to say that the roles of the series capacitance and series resistance are swapped in the case of a purely resistive matrix.

A disadvantage of this and the preceding embodiment is that four amplifiers are needed in each case, because the real and imaginary parts arise only as a result of the series capacitances and resistances. It must be remembered that every series capacitance and series resistance has both a real part and an imaginary part as a result of the phase shift of the input signal, necessitating the additional number of amplifiers.

Another embodiment is characterized in that the matrix consists of capacitive elements divided, per matrix coefficient, into positive real and negative real and also positive imaginary and negative imaginary capacitances, wherein the real and imaginary capacitances having the same arithmetic sign are each connected to a dedicated bit line and an input signal with a 90° phase shift is able to be applied to the imaginary capacitances and two phase-sensitive amplifiers for the real and imaginary output values are connected to each of the bit lines.

In the last two embodiments, the phase shift of the matrix was achieved by way of series capacitances and series resistances. In this embodiment, the phase shift is achieved by way of a 90° phase shift in the input signal. The matrix has a second set of word lines, to which the input signal for the imaginary elements of the matrix, with a 90° phase shift, is applied. Exclusively the imaginary elements are connected to these word lines. The imaginary and real components having identical arithmetic signs (positive and negative) each flow onto one bit line together. The advantage of this assembly is that again only two amplifiers are needed.

In a last embodiment, the matrix consists of resistive elements divided, per matrix coefficient, into a positive real (20) and a negative real (21) and also a positive imaginary (22) and a negative imaginary (23) resistance, wherein the real and imaginary resistances having the same arithmetic sign are each connected to a dedicated bit line (4) and an input signal (24) with a 90° phase shift is applied to the imaginary resistances (23) and two phase-sensitive amplifiers (8) for the real and imaginary output values are connected to each of the bit lines (4).

This embodiment is identical to the preceding one with the difference that the matrix consists of resistive elements.

The invention will be explained in more detail below on the basis of multiple exemplary embodiments.

### BRIEF DESCRIPTION OF THE DRAWINGS

FIG. 1 shows a matrix assembly containing resistive and capacitive elements to depict the matrix coefficients.

FIG. 2 shows an assembly for the phase-sensitive amplifier.

FIG. 3 shows a capacitive matrix assembly containing series capacitances and series resistances.

FIG. 4 shows a resistive matrix assembly containing series capacitances and series resistances.

FIG. 5 shows a capacitive matrix assembly with an input signal having a 90° phase shift for the imaginary part.

FIG. 6 shows a resistive matrix assembly with an input signal having a 90° phase shift for the imaginary part.

### DETAILED DESCRIPTION

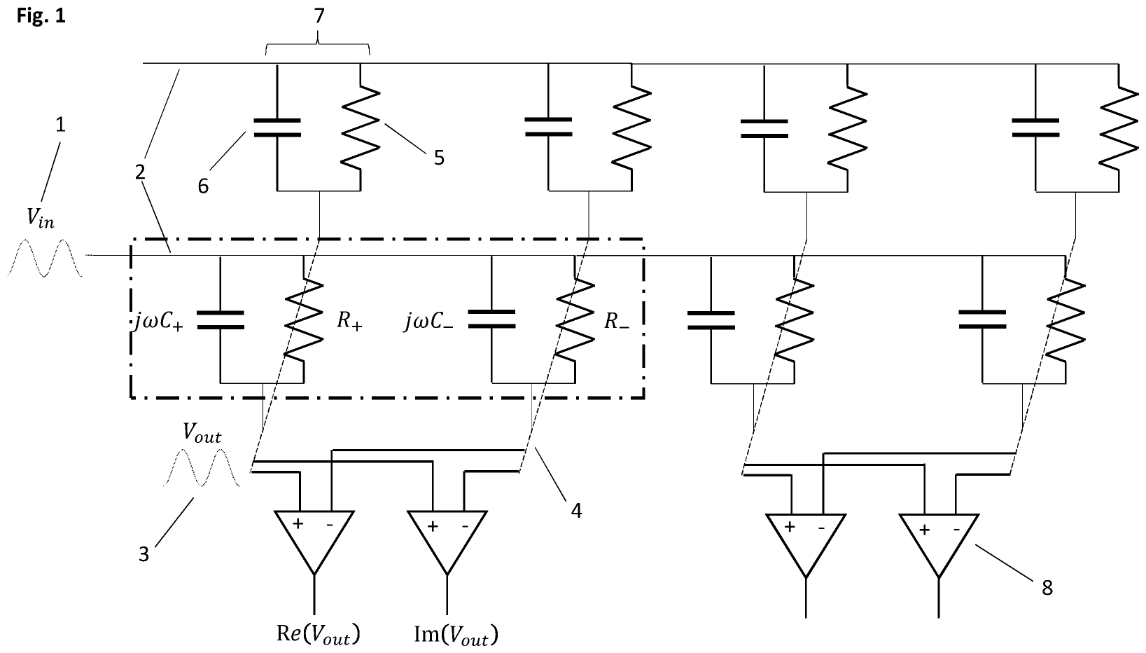

As depicted in FIG. 1, a matrix may be used in which the coefficients are represented by capacitive and resistive elements in order to depict the real and imaginary parts. The horizontal lines are the word lines (2) to which the input values (1) are applied. The output values (3) come from the bit lines (4). The mixed capacitive-resistive elements (7) can be divided into capacitive (6) and resistive (5) elements and each depict the imaginary and real parts. A differential approach is used in this depiction, and so each matrix coefficient consists of four elements. Each of the bit lines has two phase-sensitive amplifiers (8) on it in order to determine the real and imaginary output values.

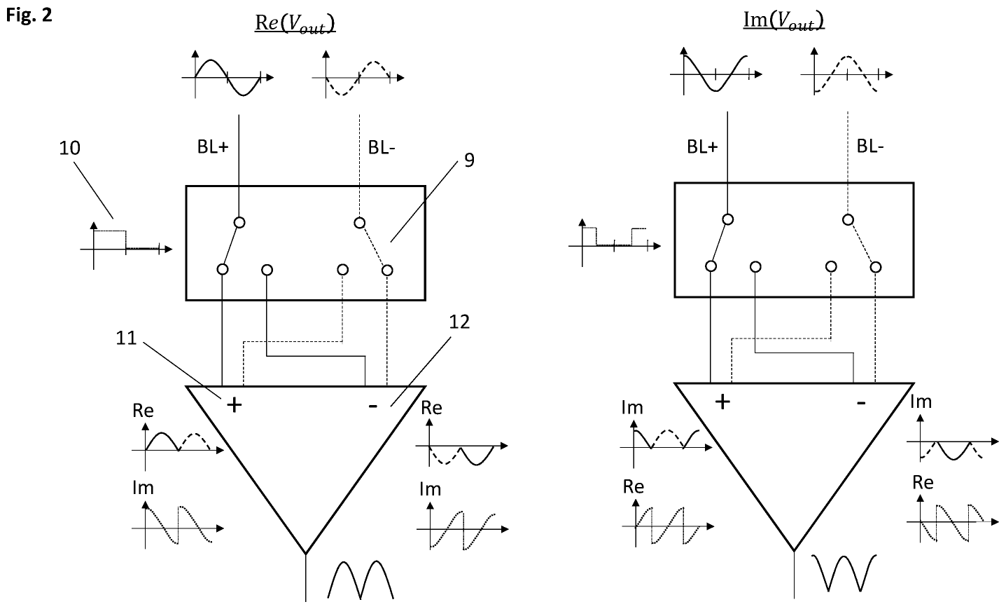

FIG. 2 depicts an embodiment for the phase-sensitive amplifier (8). The positive and negative bit lines (4) are subtracted from one another by virtue of each differential amplifier having two switches (9) connected upstream of it that operate in opposition and control the connection between the bit lines (4) and the noninverting (11) and inverting (12) inputs of the amplifier. The switches are controlled by way of a clock signal (10). For the real part of the output signal, the following applies at the amplifier for detecting the real component of the output value (3) (right-hand side of FIG. 2):

In general, the clock signal (10) is in phase with the real part of the output signal such that the positive and negative halves of the sinusoidal signal are always switched. That is to say that, in FIG. 2, first (clock signal=1) the positive half of the signal on the positive bit line (4) (BL₊) is connected to the noninverting input (11), while the negative half of the signal on the negative bit line (BL.) is connected to the inverting input (12). While the clock signal (10) is zero, the conditions turn around and the negative half of the positive bit line signal is connected to the inverting input (12), while the positive half of the negative bit line signal is connected to the noninverting input (11). In this way, a rectified sinusoidal signal having a large DC component that can be integrated or that can be filtered is produced at the output of the amplifier.

For the imaginary component of the bit line signal at the amplifier for the real part, the 90° phase shift always covers the positive and negative components of the signal equally, and so this signal has only an AC component and is filtered out.

The left-hand side in FIG. 2 is responsible for the imaginary component of the bit line signal, and the clock signal (10) has a 90° phase shift, which means that the switching conditions are again identical to the right-hand side.

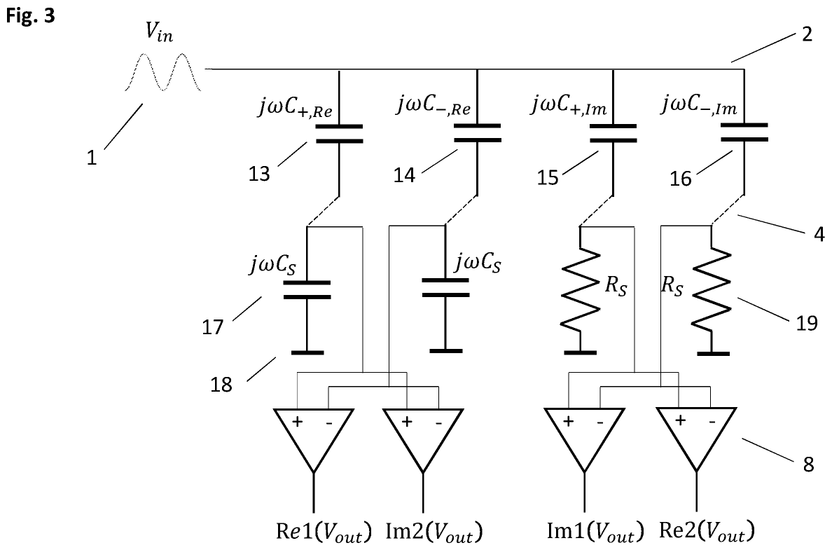

FIG. 3 shows a matrix containing purely capacitive elements (6). The phase shift of the elements is achieved by way of series capacitances (17) and series resistances (19) on the bit line, which are connected to ground (18). The voltage drop across these is detected by the phase-sensitive amplifiers (8).

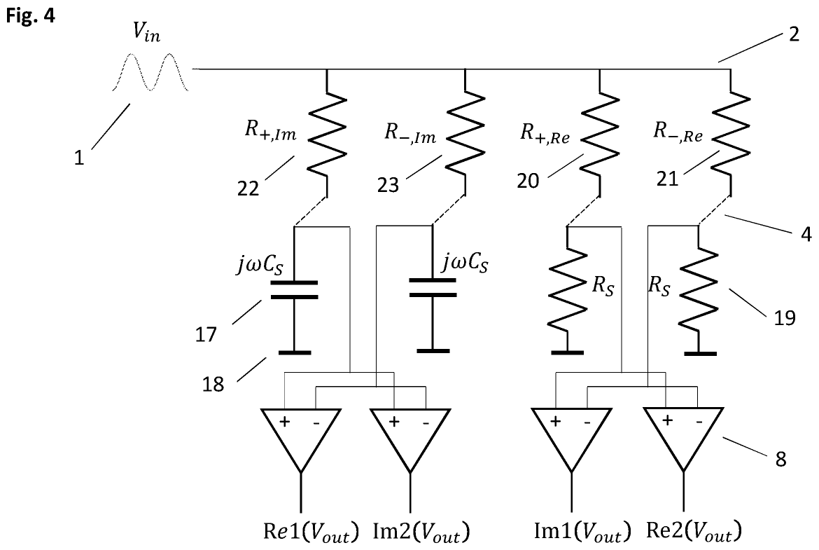

FIG. 4 shows the same matrix containing purely resistive elements (5), the function of the series resistances (19) and series capacitances (17) now being swapped.

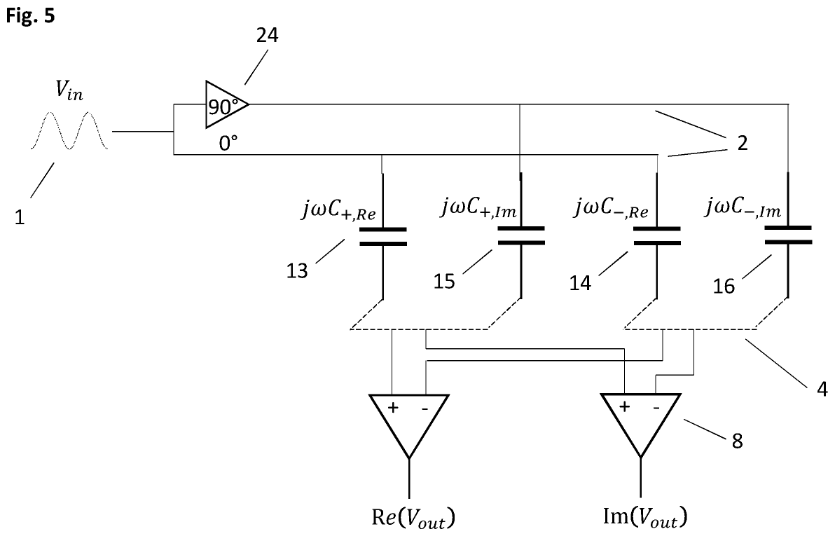

Capacitive elements (6) are again used in FIG. 5, the 90° phase shift of the imaginary part now being achieved by way of a 90° phase shift of the input signal. Said input signal is applied to a second word line (2), which is connected only to the imaginary capacitances. The real and imaginary parts having identical arithmetic signs each flow onto a dedicated bit line (4). Only two amplifiers (8) are required, which is an advantage over the embodiment in FIGS. 3 and 4.

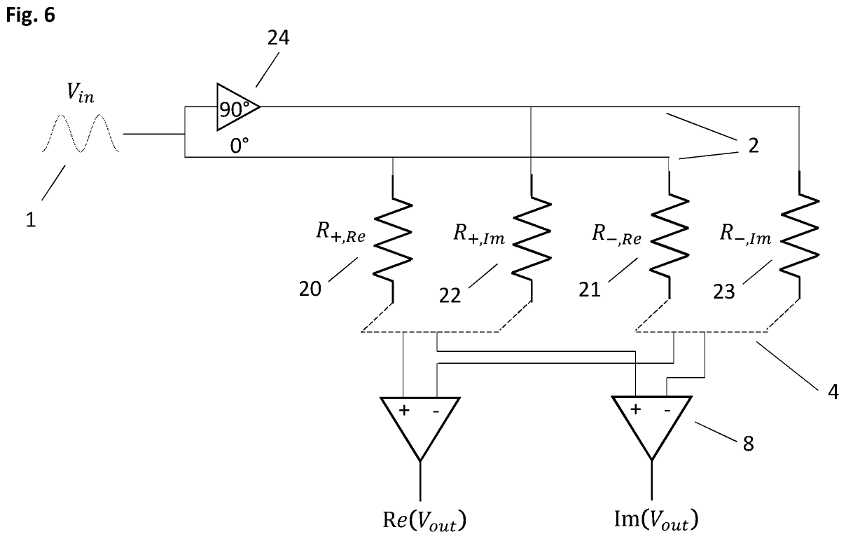

FIG. 6 shows the same assembly as in FIG. 5 with resistive elements (5).

### LIST OF REFERENCE SIGNS

1 input values
2 word lines
3 output values
4 bit lines
5 resistive devices
6 capacitive devices
7 mixed resistive-capacitive devices
8 phase-sensitive amplifier
9 input-side switches
10 clock signal
11 noninverting input
12 inverting input
13 positive real capacitances
14 negative real capacitances
15 positive imaginary capacitances
16 negative imaginary capacitances
17 series capacitance
18 ground connection
19 series resistance
20 positive real resistances
21 negative real resistances
22 positive imaginary resistances
23 negative imaginary resistances
24 input signal with 90° phase shift

1.-9. (canceled)

10. A matrix assembly, comprising:
a matrix of resistive devices (5), wherein resistance values of the resistive devices (5) represent coefficients of a discrete Fourier matrix;
word lines (2), wherein values that represent a first set of input values (1) can be applied to the word lines (2) the input values (1) being defined by phase or amplitude;
bit lines (4), wherein values that represent a second set of output values (3) can be applied to the bit lines (4);
a current amplifier that is able to be connected to the bit lines (4) and sums the output values (3); and
capacitive elements (6) that are designed to be able to store a capacitive value.

11. The matrix assembly as claimed in claim 10,
wherein the capacitive elements (6) are memcapacitive elements.

12. The matrix assembly as claimed in claim 10,
wherein the input values are additionally defined by a number of periods (1).

13. The matrix assembly as claimed in claim 10,
wherein the current amplifier is a phase-sensitive amplifier.

14. The matrix assembly as claimed in claim 13,
wherein the phase-sensitive amplifier (8) contains two input-side switches (9) that switch in opposition, and
wherein a switching state is determined by a clock signal (10), and
wherein clock signals for a real part have a 0° phase shift and clock signals for an imaginary part have a 90° phase shift,
wherein half-cycles of the output signal are always connected to noninverting (11) and inverting (12) inputs of the phase-sensitive amplifier (8).

15. The matrix assembly as claimed in claim 10,
wherein the resistance value of the resistive devices (5) represents a real part of the coefficients of the matrix and the capacitance value of the capacitive elements (6) represents an imaginary part of the coefficients of the matrix.

16. The assembly as claimed in claim 10,
wherein the matrix consists exclusively of capacitive elements (6) divided, per matrix coefficient, into positive real (13) and negative real (14) and also positive imaginary (15) and negative imaginary (16) capacitive elements (6), and
wherein a series capacitance (17) is connected in series with a ground connection (18) on the real bit lines (4) and a series resistance (19) is arranged in series with the ground connection (18) on the imaginary bit lines, and
wherein voltage drops across the series capacitance (17) and the series resistance (19) are able to be measured by phase-sensitive amplifiers (8).

17. The assembly as claimed in claim 13,
wherein the matrix consists exclusively of resistive elements (5) divided, per matrix coefficient, into positive real (20) and negative real (21) and also positive imaginary (22) and negative imaginary (23) resistances, and
wherein a series resistance (19) in relation to a ground connection (18) is on the real bit lines (4) and a series capacitance (17) in relation to the ground connection (18) is arranged on the imaginary bit lines, and
wherein voltage drops across the series resistances (19) and the series capacitances (17) are able to be measured by the phase-sensitive amplifiers (8).

18. The matrix assembly as claimed in claim 10,
wherein the matrix consists of capacitive elements (6) divided, per matrix coefficient, into positive real (13) and negative real (14) and also positive imaginary (15) and negative imaginary (16) capacitances,
wherein the real and imaginary capacitances having the same arithmetic sign are each connected to a dedicated bit line (4) and an input signal (24) with a 90° phase shift is able to be applied to the imaginary capacitances (15, 16) and two phase-sensitive amplifiers (8) for the real and imaginary output values are connected to each of the bit lines (4).

19. The assembly as claimed in claim 10,
wherein the matrix consists of resistive elements divided, per matrix coefficient, into a positive real (20) and a negative real (21) and also a positive imaginary (22) and a negative imaginary (23) resistance, wherein the real and imaginary resistances having the same arithmetic sign are each connected to a dedicated bit line (4) and an input signal (24) with a 90° phase shift is applied to the imaginary resistances (23) and two phase-sensitive amplifiers (8) for the real and imaginary output values are connected to each of the bit lines (4).
